(19) United States
(12) Patent Application Publication
(10) Pub. No.: US 2008/0133165 A1
(43) Pub. Date: Jun. 5, 2008

(54) TEST APPARATUS AND DEVICE INTERFACE

(75) Inventors: SATOSHI IWAMOTO, TOKYO (JP); ATSUNORI SHIBUYA, TOKYO (JP); KOICHI YATSUKA, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ADVANTEST CORPORATION, TOKYO (JP)

(21) Appl. No.: 11/763,417

(22) Filed: Jun. 14, 2007

(30) Foreign Application Priority Data
Dec. 4, 2006 (JP) 2006-327421

(51) Int. Cl. G06F 19/00; G01R 31/00

(52) U.S. Cl. 702/118; 702/117

(57) ABSTRACT

The test apparatus includes: a plurality of test modules that transmit/receive signals to/from the plurality of DUTs; a test head on which the plurality of test modules are placed; a plurality of device interface sections each of which is disposed between the test head and the plurality of test modules, includes a wiring that connects between a connector of the test head connected to the corresponding device under test and the test module and an identification information output section that outputs identification information indicative of the type of the device interface section, and is being capable of exchanging in accordance with the corresponding DUT and test module; and a control device connected to the plurality of test modules that controls the test module. Each test module includes: a reading section that reads the identification information; and a command processing section that returns the identification information to the control device.

### CROSS REFERENCE TO RELATED APPLICATION

The present application claims priority from a Japanese Patent Application No. 2006-327421 filed on Dec. 4, 2006, the contents of which are incorporated herein by reference.

### BACKGROUND

1. Technical Field

The present invention relates to a test apparatus and a device interface. Particularly, the present invention relates to a test apparatus including a device interface section that connects between a connector of a test head and a test module.

2. Related Art

Generally, a test apparatus that tests DUT (Device Under Test) has been known. The test apparatus includes a test module that inputs and outputs a signal to/from the DUT, a test head on which the test module is placed and a device interface section that connects between a connector of the test head and the test module, as disclosed, for example, in Japanese Patent Application Publication No. 2006-275986.

Here, a test apparatus being capable of exchanging the type of the device interface section placed thereon has been known. For example, a test apparatus has been known which is capable of switching a plurality of device interface sections each of which wire length between the test module and the DUT is different from each other and placing the same thereon.

In the above-described test apparatus, control programs (a test program created by a user and a diagnostic program that diagnoses the test apparatus) are switched in accordance with the type of the device interface section placed on the test head. For example, the test apparatus switches a plurality of control programs each of which delay time (delay time of the system) until a test waveform reaches a DUT after an instruction to output a test signal is issued is set differently from each other in accordance with the type of the device interface section placed thereon and executes the same. Thereby the test apparatus can execute the control program having a parameter optimally set and perform tests and adjustments.

However, in the above-described test apparatus, the type of the device interface section is designated by the user, so that any improper control program may have been executed.

### SUMMARY

Thus, an advantage of an aspect of the present invention is to provide an test apparatus and a device interface which are capable of solving the problem accompanying the conventional art. The above and other objects can be achieved by combining the features recited in independent claims. Then, dependent claims define further effective specific example of the present invention.

In order to solve the above described problems, a first aspect of the present invention provides a test apparatus that tests a plurality of devices under test. The test apparatus includes: a plurality of test modules that transmits/receives signals to/from devices under test; a test head on which the plurality of test modules are placed; a plurality of device interface sections disposed between the test head and the plurality of test modules, each of which has a wiring that connects between a connector of the test head connected to the corresponding device under test and the test module and a identification information output section that outputs identification information indicative of the type of the device interface section, and is being capable of exchanging in accordance with the corresponding device under test and test module; and a control device connected to the plurality of test modules that controls the test modules. Each of the test modules includes: a reading section that reads identification information from the corresponding device interface section; and a command processing section that returns the identification information read by the reading section to the control device in response to receiving a request command that requests to return the identification information of the corresponding device interface section from the control device.

### BRIEF DESCRIPTION OF THE DRAWINGS

FIG. 1 shows a configuration of a test apparatus according to an embodiment of the present invention along with DUTs;

FIG. 2 shows a configuration of a test module, a device interface section and a control device according to an embodiment of the present invention;

FIG. 3 shows a configuration of an identification information output section and a reading section according to a first modification of an embodiment of the present invention;

FIG. 4 shows a configuration of the test module and the device interface section according to a second modification of an embodiment of the present invention;

FIG. 5 shows a configuration of the identification information output section and the reading section according to a third modification of an embodiment of the present invention; and

FIG. 6 shows a configuration of the test module, the device interface section and the control device according to a fourth modification of an embodiment of the present invention.

### DESCRIPTION OF EXEMPLARY EMBODIMENTS

The invention will now be described based on preferred embodiments, which do not intend to limit the scope of the invention, but exemplify the invention. All of the features and the combinations thereof described in the embodiments are not necessarily essential to the invention.

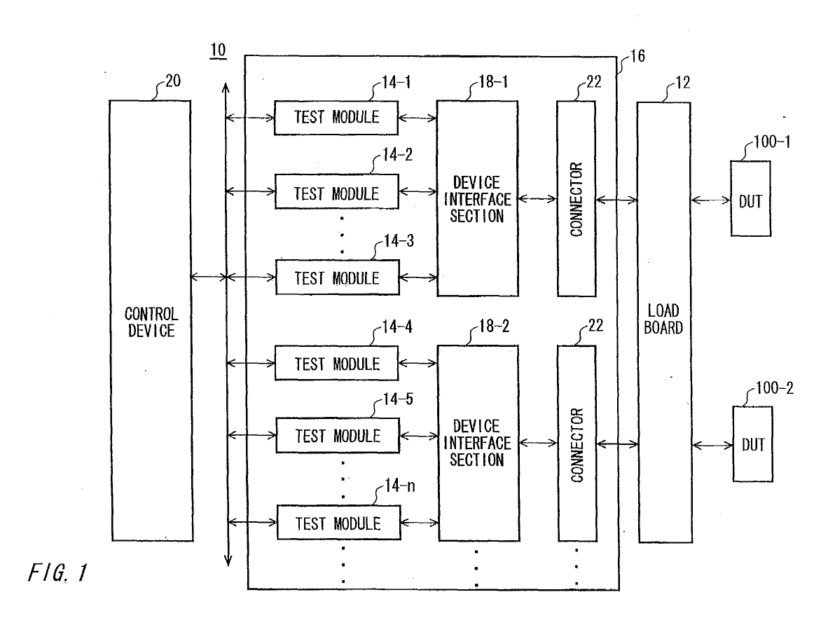

FIG. 1 shows a configuration of a test apparatus 10 according to the present embodiment along with DUTs 100. The test apparatus 10 tests a plurality of DUTs (devices under test) 100 (100-1, 100-2). Specifically, the test apparatus 10 generates test signals, provides the same to each DUT 100 and judges that each DUT 100 passes/fails based on whether an output signal outputted by each DUT 100 as the result of the operation based on the test signal is corresponding to an expected value.

The test apparatus 10 includes a load board 12, a plurality of test modules 14 (14-1 to 14-n, . . . where, n is any integer equal to or more than 2), a test head 16, a plurality of device interface sections 18 (18-1, 18-2, . . . ) and a control device 20. The plurality of DUTs 100 are placed on the load board 12, and the load board 12 connects between each of the plurality of test modules 14 and the corresponding DUT 100.

Each of the test modules 14 (14-1 to 14-n, . . . ) transmits/receives signals to/from the corresponding DUT 100 in order to test the corresponding DUT 100 based on the test program and test data received from the control device 20, for example. Each test module 14 generates a test signal from test data in accordance with a sequence defined by the test program and provides the test signal to a terminal of the corresponding DUT 100, for example. Moreover, the test module 14 acquires an output signal outputted by the corresponding DUT 100 as the result of the operation in accordance with the test signal from the terminal of the DUT 100 and compares the same with the expected value. Then, the test module 14 transmits the result obtained by comparing the output signal with the expected value to the control device 20 as a test result.

The plurality of test modules 14 are placed on the test head 16. For example, the test head 16 has a housing, the load board 12 is placed on the upper portion of the exterior of the housing, and the plurality of test modules 14 are placed inside the housing.

Each device interface section 18 is disposed between the test head 16 and the plurality of test modules 14. Each device interface section 18 connects between the connector 22 of the test head 16 and the test module 14 through an electrical wiring. The connector 22 of the test head 16 is electrically connected to the terminal of the DUT 10 through the load board 12. One test module 14 may be connected to one device interface section 18, or two or more test modules 14 may be connected to one device interface section 18.

The control device 20 is connected to the plurality of test modules 14 and controls the test modules 14. The control device 20 may be embodied by a computer independent of the test head 16.

The control device 20 stores the test program and test data used to test the DUTs 100 in the test modules 14, for example. Next, the control device 20 instructs the test modules 14 to start to test based on the test program and test data and causes the test modules 14 to perform the test. Then, the control device 20 receives an interrupt indicative of the termination of the test, a test result and so fourth from the test modules 14 and causes the test modules 14 to perform the next test based on the test result. Moreover, before testing, the control device 20 may diagnose whether the test modules 14 normally operate by executing a diagnostic program, for example.

The test apparatus 10 having the above-described feature can test the DUTs 100. In addition, the test apparatus 10, for example, can diagnose each test module 14 before testing and select the test program in accordance with the diagnostic result to perform the test.

Here, the test apparatus 10 includes device interface sections 18 which can be exchanged in accordance with the corresponding DUT 100 and test module 14. The test apparatus 10 may include device interface sections 18 each of which wire length, wiring pattern and so forth are different from each other dependent on the type of the DUTs 100 (e.g. the type of input/output signals, pin assignment, the kind of the contents of signal processing and so fourth) and the type of the test modules 14 connected thereto (the type of signals inputted to the input terminal, the type of signals outputted from the output terminal, terminal assignment and so forth). Thereby the test apparatus 10 can include each device interface section 18 having the optimum wire length and wiring pattern for each of the DUTs 100 and the test modules 14.

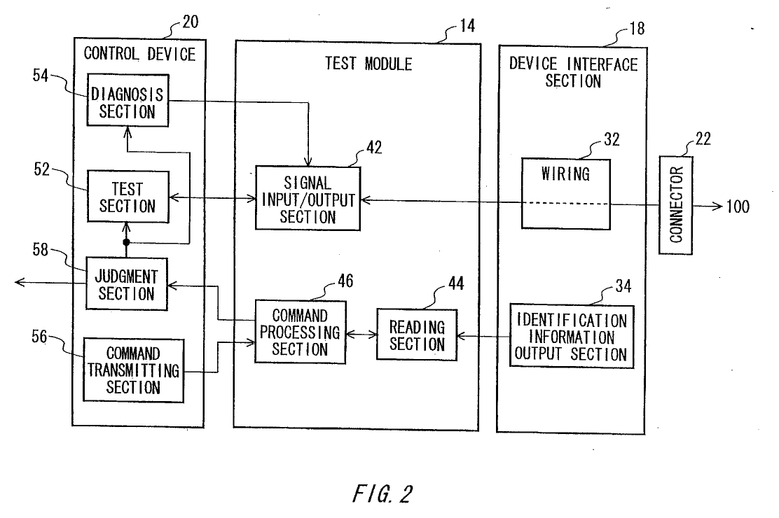

FIG. 2 shows a configuration of the test module 14, the device interface section 18 and the control device 20 according to the present embodiment. Each device interface section 18 includes a wiring 32 and an identification information output section 34.

The wiring 32 connects between the connector 22 of the test head 16 connected to the corresponding DUT 100 and the test module 14. For example, the wiring 32 may be such as a coaxial cable that connects between the connector of the test module 14 and the connector 22 of the test head 16. The signal input/output section 42 can provide the test signal to a predetermined terminal of the corresponding DUT 100 and input the output signal outputted from the predetermined terminal of the corresponding DUT 100 because the above-described wiring 32 is provided.

The identification information output section 34 outputs identification information indicative of the type of the device interface section 18. For example, the identification information output section 34 outputs identification information uniquely set for each type of the wire length, the wiring pattern and so forth of the device interface section 18. The identification information output section 34 may output the identification information as binary data stored in a memory such as a ROM through such as a parallel bus, a serial bus and an I2C bus, for example.

Each test module 14 includes a signal input/output section 42, a reading section 44 and a command processing section 46. Here, when two or more test modules 14 are connected to one device interface section 18, at least a representative test module 14 among the plurality of test modules 14 connected to one device interface section 18 includes the reading section 44 and the command processing section 46. That is, the test modules 14 other than the representative one do not include the reading section 44 and the command processing section 46. Here, the representative test module 14 is an example of the test module according to the present invention.

The signal input/output section 42 outputs the test signal to the corresponding DUT 100 through the wiring 32 of the device interface section 18.

### In addition, the signal input/output section 42 inputs an output signal outputted by the DUT 100 in accordance with the test signal through the wiring 32 of the device interface section 18.

The reading section 44 reads identification information from the identification information output section 34 of the corresponding device interface section 18. The reading section 44 may read identification information as binary data stored in a memory such as a ROM through such as a bus, for example.

The command processing section 46 receives from the control device 20 a request command that requests to return the identification information of the corresponding device interface section 18 from the control device 20. Then, the command processing section 46 returns the identification information read by the reading section 44 to the control device 20 in response to receiving the request command. The command processing section 46 may transmits/receives commands to/from the control device 20 through a bus such as a PCI, for example. Receiving the request command from the control device 20, the command processing section 46 causes the reading section 44 to read identification information. Then, the command processing section 46 may acquire the identification information obtained as the result of the reading operation of the reading section 44 and return the acquired identification information to the control device 20.

The control device 20 includes a test section 52, a diagnosis section 54, a command transmitting section 56 and a judgment section 58. The test section 52 performs controls of testing the DUTs 100. For example, the CPU of the control device 20 executes the test control program created by the user of the test apparatus 10, so that the control device 20 functions as a test section 52. The test section 52 stores the test program and test data used to test the DUTs 100 on the test modules 14 and causes the test modules 14 to test the DUTs 100 based on the test program and the test data, for example.

The command transmitting section 56 transmits a request command that requests to return the identification information of the connected device interface section 18 to the command processing section 46 of the test module 14 to be controlled. The command transmitting section 56 may transmit the request command to the test module 14 to be controlled before testing, for example.

The diagnosis section 54 performs controls of diagnosing the test apparatus 10. In order to function the control device 20 as the diagnosis section 54, the CPU of the control device 20 executes a diagnostic program, for example. The diagnosis section 54 diagnoses the operation of the test modules 14 before testing by the test section 52, for example.

When the test apparatus 10 is diagnosed, the judgment section 58 judges the type of the device interface section 18. In order to function the control device 20 as the judgment section 58, the CPU of the control device 20 executes the diagnostic program, for example. The judgment section 58 acquires the identification information returned from the command processing section 46 of the test module 14 to be controlled. The judgment section 58 judges whether the device interface section 18 conforming to the control program which is executed on the control device 20 to control the test module 14 to be controlled is connected to the test module 14 to be controlled based on the identification information returned from the test module 14 to be controlled.

In addition, the test section 52 may previously store a plurality of test control programs in accordance with the type of the device interface section 18. Then, at testing, the test section 52 may select one test control program associated with the identification information returned from the test module 14 to be controlled according to the result by the judgment section 58 and execute the same. In addition, the test section 52 may previously store a plurality of programs in accordance with the type of the device interface section 18 as test programs which should be executed by the test modules 14, for example. Then, at testing, the test section 52 may select one test program associated with the identification information returned from the test module 14 to be controlled and provide the same to the corresponding test module 14 according to the result by the judgment section 58.

The diagnosis section 54 may previously store a plurality of diagnostic programs in accordance with the type of the device interface sections 18, for example. Then, at diagnosing, the diagnosis section 54 may select the diagnostic program associated with the identification information returned from the test module 14 to be controlled and execute the same to diagnose the device interface section 18 identified by the identification information and the test module 14 to be controlled.

The test apparatus 10 having the above-described feature can judge whether the device interface section 18 having the type conforming to the control program (the test program and the diagnostic program) executed on the test apparatus 10 is connected to the test head 16. Thereby the test apparatus 10 can prevent from operating under the condition that any improper device interface section 18 is connected thereto. Moreover, the test apparatus 10 can select the control program (the test program and the diagnostic program) conforming to the type of the device interface section 18 connected to the test head 16 and execute the same. Thereby the test apparatus 10 can perform a test conforming to the device interface section 18 connected to the test head 16.

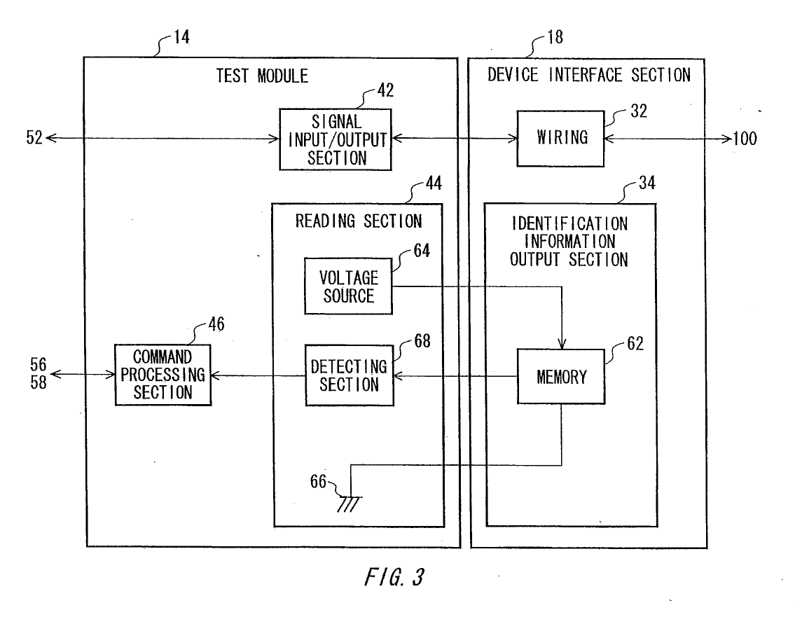

FIG. 3 shows a configuration of the identification information output section 34 and the reading section 44 according to a first modification of the present embodiment. The test apparatus 10 according to the present modification has a configuration and a function approximately the same as those of the test apparatus 10 as shown in FIG. 1. Hereinafter, components of the modification having the configuration and the function approximately the same as those of the components as shown in FIG. 1 and FIG. 2 have reference numerals the same as those of the components as shown in FIG. 1 and FIG. 2, so that the description is omitted except for the difference.

The identification information output section 34 of each device interface section 18 includes a memory 62 on which identification information is stored, such as a ROM. Each test module 14 supplies an operating voltage to operate the memory 62 on the corresponding device interface section 18.

The reading section 44 of each test module 14 may include a voltage source 64, a ground 66 and a detecting section 68, for example. The voltage source 64 and the ground 66 supplies the operating voltage to the memory 62 included in the identification information output section 34 of the corresponding device interface section 18. The detecting section 68 reads the identification information stored in the memory 62 from the memory 62 to which the operating voltage is supplied.

The above-described test apparatus 10 can output identification information from each device interface section 18. Moreover, in the above-described test apparatus 10, the device interface section 18 does not need such as a voltage source, so that the device interface section 18 may have a simple configuration.

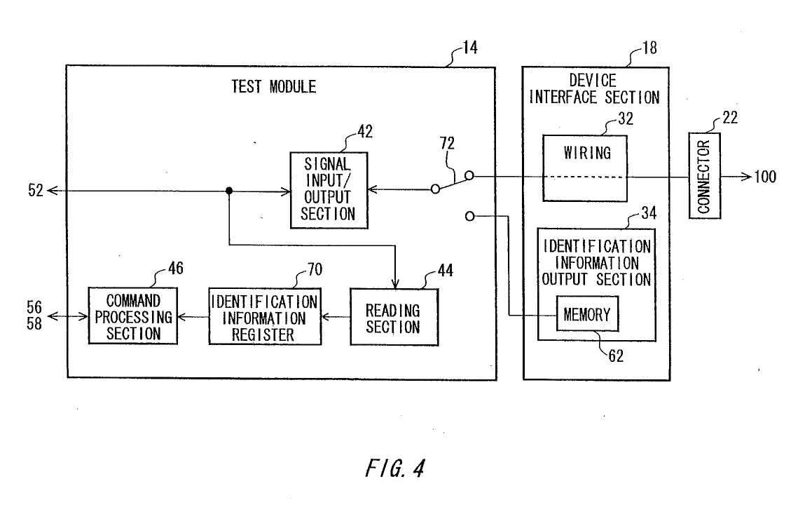

FIG. 4 shows a configuration of the test module 14 and the device interface section 18 according to a second modification of the present embodiment. The test apparatus 10 according to the present modification has the configuration and the function approximately the same as those of the test apparatus 10 as shown in FIG. 1. Hereinafter, components of the modification having the configuration and the function approximately the same as those of the components as shown in FIG. 1 and FIG. 2 have reference numerals the same as those of the components as shown in FIG. 1 and FIG. 2, so that the description is omitted except for the difference.

The identification information output section 34 of each device interface section 18 includes a memory 62 on which identification information is stored, such as a ROM. The memory 62 may be provided from the test module 14 of which operating voltage is corresponding thereto as well as the memory 62 according to the first modification.

Each test module 14 further includes an identification information register 70 and a switch section 72. The identification information register 70 stores therein the identification information read by the reading section 44.

The switch section 72 is provided corresponding to at least one signal input/output section 42 in the test module 14. In order to read the identification information from the corresponding device interface section 18, the switch section 72 connects the at least one signal input/output section 42 to the memory 62. In addition, in order to test the corresponding DUT 100, the switch section 72 connects the at least one signal input/output section 42 to the DUT 100 through the wiring 32.

Before receiving a request command that requests to return the identification information, the reading section 44 connects the at least one signal input/output section 42 to the memory 62 by the switch section 72 and reads the identification information through the at least one signal input/output section 42. Then, the reading section 44 stores the read identification information on the identification information register 70. The command processing section 46 returns the identification information stored in the identification information register 70 to the control device 20 in response to receiving the request command from the control device 20.

The above-described test apparatus 10 can read identification information by using the signal input/output section 42, so that the reading section 44 may have a simple configuration. In addition, the test apparatus 10 previously reads the identification information of the device interface section 18 before receiving the request command of the identification information, so that the reading section 44 does not need to read through the signal input/output section 42 again.

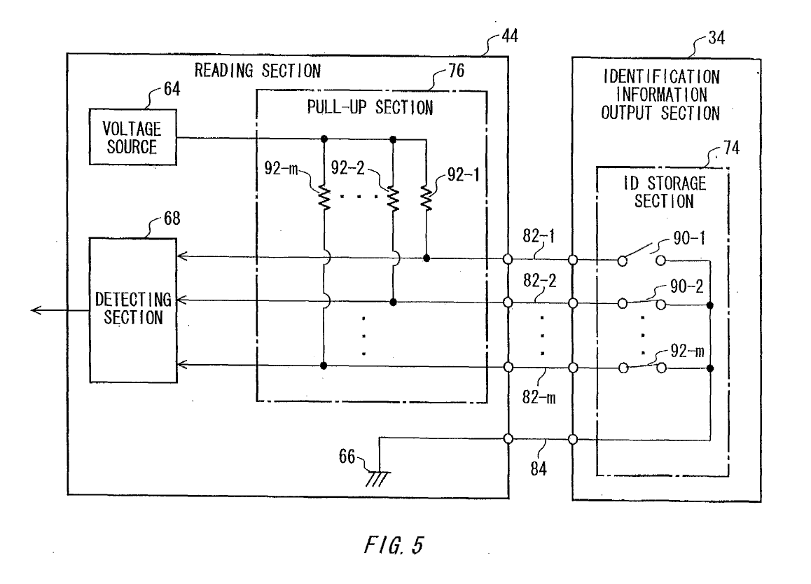

FIG. 5 shows a configuration of the identification information output section 34 and the reading section 44 according to a third modification of the present embodiment. The test apparatus 10 according to the present modification has the configuration and the function approximately the same as those of the test apparatus 10 according to the first modification. Hereinafter, components of the modification having the configuration and the function approximately the same as those of the components as shown in FIG. 1 to FIG. 3 have reference numerals the same as those of the components as shown in FIG. 1 to FIG. 3, so that the description is omitted except for the difference.

The identification information output section 34 of each device interface section 18 includes an ID storage section 74 instead of the memory 62. The ID storage section 74 includes a plurality of on/off switches 90 (90-1-90-m) corresponding to each bit(1-m) of the identification information. Each on/off switch 90 is turned on (connected) or turned off (opened) between both terminals thereof in accordance with the corresponding bit value of the identification information. For example, each on/off switch 90 may be set by the user such that each on/off switch 90 is turned off when the corresponding bit of the identification information is 1 and turned on when the corresponding bit of the identification information is 0.

One terminal of each on/off switch 90 is connected to the corresponding bit line among a plurality of signal lines 82 (82-1-82-m) that transmit each bit value of the identification information in parallel from the identification information output section 34 to the reading section 44. In addition, the other terminal of each on/off switch 90 is connected to a ground line 84 to which the ground 66 is connected.

The reading section 44 further includes a pull-up section 76. The pull-up section 76 includes a plurality of resistors 92 (92-1 to 92-m) corresponding to each bit (1-m) of the identification information. One terminal of each resistor 92 is connected to the corresponding bit line among a plurality of signal lines 82 (82-1-82-m). In addition, the other terminal of each resistor 92 is connected to the voltage source 64. By such pull-up section 76, the signal line 82 of which on/off switch 90 is turned on (connected) is ground potential, and the signal line 82 of which on/off switch 90 is turned off (opened) is power supply potential.

The detecting section 68 detects the potential of the plurality of signal lines 82 (82-1 to 82-m) and judges each bit value of the identification information based on the detected potential. The detecting section 68, for example, judges each bit of the identification information is 1 when the potential of the signal line 82 corresponding to each bit of the identification information is the power supply potential. Alternatively, the detecting section 68 judges each bit of the identification information is 0 when the potential of the signal line 82 corresponding to each bit of the identification information is the ground potential.

As described above, the ID storage section 74 included in the identification information output section 34 of each device interface section 18 determines the potential for each of the plurality of signal lines 82 that connects the identification information output section 34 and the reading section 44 based on each bit value of the identification information. Thereby the test apparatus 10 can cause the identification information output section 34 having a simple configuration to output the identification information.

Here, the pull-up section 76 may not be included in the reading section 44 but may be included in the identification information output section 34. In addition, the identification information output section 34 may include the ID storage section 74 instead of the memory 62 in the test apparatus 10 as shown in FIG. 4. When the identification information output section 34 of the test apparatus 10 as shown in FIG. 4 includes the ID storage section 74, the test module 14 or the device interface section 18 further includes the pull-up section 76.

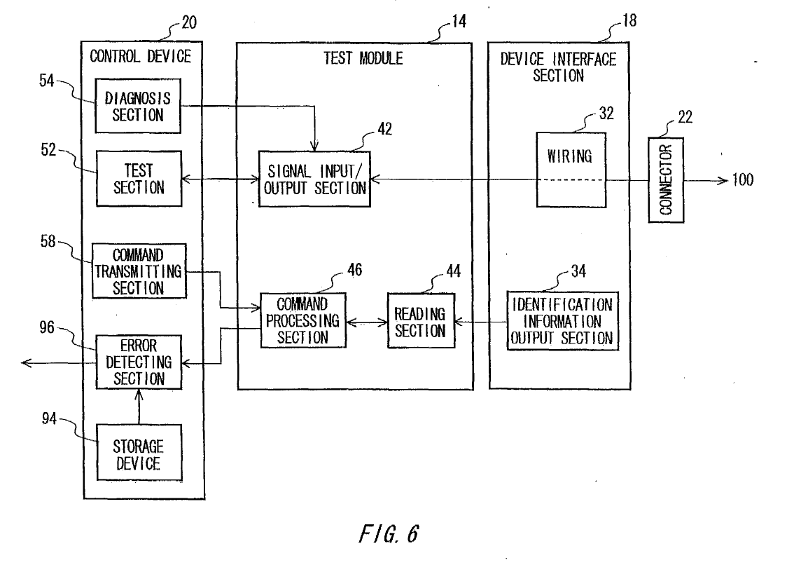

FIG. 6 shows a configuration of the test module 14, the device interface section 18 and the control device 20 according to a fourth modification of the present embodiment. The test apparatus 10 according to the present modification has the configuration and the function approximately the same as those of the test apparatus 10 as shown in FIG. 1. Hereinafter, components of the modification having the configuration and the function approximately the same as those of the components as shown in FIG. 1 and FIG. 2 have reference numerals the same as those of the components as shown in FIG. 1 and FIG. 2, so that the description is omitted except for the difference.

The control device 20 further includes a storage device 94 and an error detecting section 96 instead of the judgment section 58. The storage device 94 stores a configuration file on which the identification information indicative of the device interface section 18 to be connected to each test module 14 is stored. The storage device 94 may store a configuration file on which the configuration and the relation of connection among the test modules 14, the device interface sections 18 and the other hardware which should be placed on the test apparatus 10 are described, for example.

The error detecting section 96 acquires the identification information returned from the test module 14 to be controlled. The error detecting section 96 retrieves the configuration file stored in the storage device 94 and acquires the identification information of the device interface section 18 which should be connected to the test module 14 to be controlled. Then, the error detecting section 96 detects an error indicating that an improper device interface section 18 is connected when the identification information returned from the test module 14 to be controlled is different from the identification information indicative of the device interface section 18 to be connected to the test module 14 to be controlled, which is stored in the configuration file. The above-described test apparatus 10 can detect the improper connection of each device interface section 18 and avoid performing any test and diagnosing under the condition that the device interface 18 is improperly connected.

While the invention has been described by way of the exemplary embodiments, it should be understood that those skilled in the art might make many changes and substitutions without departing from the spirit and scope of the invention. It is obvious from the definition of the appended claims that the embodiments with such modifications also belong to the scope of the invention.

What is claimed is:

1. A test apparatus that tests a plurality of devices under test, comprising:
a test module that transmits/receives signals to/from the device under test;
a device interface section being exchangeable that includes a wiring that connects between a connector connected to the device under test and the test module, and an identification information output section that outputs identification information indicative of the type of the device interface section; and
a control device that controls the test module, wherein
the test module including:
a reading section that reads the identification information from the corresponding device interface section; and
a command processing section that returns the identification information read from the reading section to the control device.

2. The test apparatus as set forth in claim 1 further comprising:
a plurality of the test modules;
a test head on which the plurality of test modules are placed; and
a plurality of the device interface sections, wherein
each of the device interface sections is disposed between the test head and the plurality of test modules, includes a wiring that connects between a connector of the test head connected to the corresponding device under test and the test module and an identification information output section that outputs identification information indicative of the type of the device interface section, and is being capable of exchanging in accordance with the corresponding device under test and test module,
the control device is connected to the plurality of test modules and controls the test modules, and
the command processing section returns the identification information read from the reading section to the control device in response to receiving a request command that requests to return the identification information of the corresponding device interface section from the control device.

3. The test apparatus as set forth in claim 2, wherein the identification information output section of each device interface section includes a memory on which the identification information is stored.

4. The test apparatus as set forth in claim 3, wherein each of the test modules supplies an operating voltage to operate the memory on the corresponding device interface section.

5. The test apparatus as set forth in claim 4, wherein each of the test modules further including:
a plurality of signal input/output sections that outputs a test signal to the corresponding device under test and inputs an output signal outputted from the device under test in accordance with the test signal; and
a switching section that connects at least one of the signal input/output sections to the memory when the identification information is read from the corresponding device interface section and connects the at least one signal input/output section to the device under test when the corresponding device under test is tested.

6. The test apparatus as set forth in claim 5, wherein
each of the test modules further includes an identification information register that stores the identification information read by the reading section,
the reading section connects the at least one signal input/output section to the memory by the switching section, reads the identification information through the at least one signal input/output section and stores the same on the identification information register before receiving the request command that requests to return the identification information, and
the command processing section returns the identification information stored in the identification information register to the control device in response to receiving the request command from the control device.

7. The test apparatus as set forth in claim 2, wherein the identification information output section of each of the device interface sections defines the potential for each of a plurality of signal lines that connects the identification information output section to the reading section in accordance with each bit value of the identification information.

8. The test apparatus as set forth in claim 2, wherein the control device includes a command transmitting section that transmits the request command to the test module to be controlled; and
a judgment section that judges whether the device interface section conforming to a control program executed on the control device that controls the test module to be controlled is connected to the test module to be controlled based on the identification information returned from the test module to be controlled.

9. The test apparatus as set forth in claim 2, wherein the control device including:
a command transmitting section that transmits the request command to the test module to be controlled; and
a diagnosis processing section that selects and executes a diagnostic program associated with the identification information returned from the test modules to be controlled, and diagnoses the device interface section identified by the identification information and the test module to be controlled.

10. The test apparatus as set forth in claim 2, wherein the control device including:
a storage device that stores therein a configuration file in which identification information indicative of the device interface section to be connected to each of the test modules is stored;
a command transmitting section that transmits a command that requests to return the identification information to the test module to be controlled; and
an error detecting section that detects an error indicating that the device interface section which is improper is connected when the identification information returned from the test module to be controlled is different from the identification information indicative of the device interface which should be connected to the test module to be controlled, which is stored in the configuration file.

11. A device interface for use in a test apparatus that tests a device under test, comprising:
a wiring that connects a test module that transmits/receives a signal to/from the device under test and a connector connected to the device under test; and
an identification information output section that identifies the type of the device interface and outputs identification information read by the test module.

12. The device interface as set forth in claim 11, further comprising a memory that operates according to an operating voltage supplied from the test module and stores therein the identification information.
